(19) United States
(12) Patent Application Publication
(10) Pub. No.: US 2025/0380543 A1
(43) Pub. Date: Dec. 11, 2025

(54) METHOD FOR TRANSFERRING MICRO LIGHT-EMITTING ELEMENTS

(71) Applicant: LC SQUARE CO., LTD., Hwaseong-si, Gyeonggi-do (KR)

(72) Inventors: Je Hyuk CHOI, Yongin-si, Gyeonggi-do (KR); Chang Wan KIM, Hwaseong-si, Gyeonggi-do (KR); Yun Gwon WANG, Ansan-si, Gyeonggi-do (KR)

(21) Appl. No.: 18/878,008

(22) PCT Filed: Jun. 30, 2023
(86) PCT No.: PCT/KR2023/009245

§ 371 Date: Dec. 21, 2024

(30) Foreign Application Priority Data
Jun. 30, 2022 (KR) 10-2022-0080725
Jun. 29, 2023 (KR) 10-2023-0084287

(51) Int. Cl. H10H 29/03

(52) U.S. Cl. CPC H10H 29/03

(57) ABSTRACT

Provided is a method of transferring micro light-emitting devices, including providing a first substrate including a first photosensitive layer and a first adhesive layer, providing micro light-emitting devices on the first adhesive layer, patterning the first photosensitive layer and the first adhesive layer to correspond to shapes of the micro light-emitting devices, providing a second substrate, which includes a second photosensitive layer and a second adhesive layer, above the micro light-emitting devices, and irradiating light onto the first photosensitive layer through the first substrate to transfer the micro light-emitting devices onto the second substrate.

### TECHNICAL FIELD

The present invention relates to a method of transferring micro light-emitting devices, and more particularly, to a method of transferring micro light-emitting devices capable of transferring the micro light-emitting devices multiple times onto different substrates and adjusting orientations of the micro light-emitting devices as needed.

### BACKGROUND ART

With the rapid advancement of electrical and electronic technologies, there may be a need to integrate various individual devices with different technical characteristics to meet the demands of a new era and diverse consumer requirements.

Accordingly, it is crucial to have a transfer method that enables individual devices (or individual components), which are manufactured based on different technologies on a source substrate, to be mass-transferred and integrated onto a wiring substrate (or a display substrate), i.e., a target substrate (or a destination substrate), without causing damage.

### DISCLOSURE

### Technical Problem

The present invention is directed to providing a method of transferring micro light-emitting devices capable of transferring the micro light-emitting devices multiple times onto different substrates and adjusting orientations of the micro light-emitting devices as needed.

### Technical Solution

In order to achieve the above technical object, the present invention provides a method of transferring micro light-emitting devices, including providing a first substrate including a first photosensitive layer and a first adhesive layer, providing micro light-emitting devices on the first adhesive layer, patterning the first photosensitive layer and the first adhesive layer to correspond to shapes of the micro light-emitting devices, providing a second substrate, which includes a second photosensitive layer and a second adhesive layer, above the micro light-emitting devices, and irradiating light onto the first photosensitive layer through the first substrate to transfer the micro light-emitting devices onto the second substrate.

In some embodiments, the patterning of the first photosensitive layer and the first adhesive layer may be performed by anisotropic etching.

In some embodiments, the first photosensitive layer may include a material that is photodecomposable by light irradiation. In some embodiments, the first photosensitive layer may include a material that is photodecomposable in response to laser light or ultraviolet (UV) light.

In some embodiments, the second photosensitive layer and the second adhesive layer may be sequentially provided on the second substrate, and the providing of the second substrate, which includes the second photosensitive layer and the second adhesive layer, above the micro light-emitting devices may be performed such that the second adhesive layer faces the micro light-emitting devices.

In some embodiments, the method further includes, after the irradiating of light onto the first photosensitive layer through the first substrate, patterning the second photosensitive layer and the second adhesive layer to correspond to the shapes of the micro light-emitting devices, providing a third substrate, which includes a third photosensitive layer and a third adhesive layer, above the micro light-emitting devices, irradiating light onto the second photosensitive layer through the second substrate, and separating the second substrate from the micro light-emitting devices to transfer the micro light-emitting devices onto the third substrate.

In some embodiments, the patterning of the second photosensitive layer and the second adhesive layer to correspond to the shapes of the micro light-emitting devices may be performed by anisotropic etching using the micro light-emitting devices as an etching mask. In some embodiments, residual portions of the first photosensitive layer and the first adhesive layer may be removed during the patterning of the second photosensitive layer and the second adhesive layer to correspond to the shapes of the micro light-emitting devices.

In some embodiments, a material of the second photosensitive layer may be substantially the same as a material of the first photosensitive layer.

In some embodiments, in the irradiating of light onto the first photosensitive layer through the first substrate, the micro light-emitting devices may be irradiated with light while being spaced apart from the second substrate.

According to another aspect of the present invention, there is provided a method of transferring micro light-emitting devices, including providing a first substrate including a first photosensitive layer, placing micro light-emitting devices on the first photosensitive layer, patterning the first photosensitive layer so that shapes of the micro light-emitting devices are transferred, attaching a second substrate including a second photosensitive layer on top of the micro light-emitting devices, and irradiating light onto the first photosensitive layer through the first substrate to transfer the micro light-emitting devices onto the second substrate.

In some embodiments, the first substrate and the second substrate may be substantially transparent to the light irradiated onto the first photosensitive layer.

In some embodiments, the method further includes, after the irradiating of light onto the first photosensitive layer through the first substrate, patterning the second photosensitive layer to correspond to the shapes of the micro light-emitting devices, providing a third substrate, which includes a third photosensitive layer, above the micro light-emitting devices, and irradiating light onto the second photosensitive layer through the second substrate to transfer the micro light-emitting devices onto the third substrate.

In some embodiments, a material of the third photosensitive layer may be substantially the same as a material of the first photosensitive layer.

In some embodiments, a residual portion of the first photosensitive layer may be removed during the patterning of the second photosensitive layer to correspond to the shapes of the micro light-emitting devices.

### Advantageous Effects

A method of transferring micro light-emitting devices of the present invention has the effect of allowing orientations of the micro light-emitting devices to be adjusted as needed. Further, the method of transferring micro light-emitting devices of the present invention has the effect of allowing the micro light-emitting devices to be transferred onto different substrates multiple times as needed.

### BRIEF DESCRIPTION OF THE DRAWINGS

FIG. 1 is a flowchart illustrating a method of transferring micro light-emitting devices according to one embodiment of the present invention.

FIGS. 2 to 10 are perspective views or side views schematically illustrating the method of transferring micro light-emitting devices according to one embodiment of the present invention.

FIG. 11 is a flowchart illustrating a method of transferring micro light-emitting devices according to an additional embodiment of the present invention.

FIGS. 12 to 16 are side views schematically illustrating the method of transferring micro light-emitting devices according to the additional embodiment of the present invention.

### DETAILED DESCRIPTION OF THE PREFERRED EMBODIMENTS

Hereinafter, exemplary embodiments of the present inventive concept will be described in detail with reference to the accompanying drawings. However, the embodiments of the present inventive concept can be modified into many different forms, and the scope of the present inventive concept should not be construed as being limited to the embodiments described below. It is preferred that the embodiments of the present inventive concept are interpreted as being provided to offer a more complete explanation of the present inventive concept to those of ordinary skill in the art. The same reference numerals refer to the same elements throughout the specification. Furthermore, various elements and areas in the drawings are schematically illustrated. Therefore, the present inventive concept is not limited by the relative sizes or intervals illustrated in the accompanying drawings.

The terms such as first, second, and the like can be used to describe various components, but these components are not limited by these terms. The terms are used solely for the purpose of distinguishing one component from another. For example, a first component may be named a second component without departing from the scope of the claims of the present inventive concept, and conversely, the second component may also be named the first component.

The terms used in the present application are merely used to describe specific embodiments and are not intended to limit the present inventive concept. Singular expressions include plural expressions unless the context clearly indicates otherwise. In the present application, it should be understood that terms such as “comprises” or “has” are intended to specify the presence of features, numbers, steps, operations, components, parts, or combinations thereof described in the specification, and do not preclude the possibility of the presence or addition of one or more other features, numbers, operations, components, parts, or combinations thereof.

Unless otherwise defined, all terms used herein, including technical and scientific terms, have the same meaning as commonly understood by those skilled in the art to which the present inventive concept pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

When a certain embodiment can be implemented differently, a specific process sequence may be performed differently from the described order. For example, two processes described in succession may be performed substantially at the same time or performed in an order opposite to the described order.

In the accompany drawings, variations in the shapes of the illustrations as a result, for example, of manufacturing techniques and/or tolerances, are to be expected. Thus, the embodiments of the present invention should not be construed as being limited to the particular illustrated shapes of regions, but are to include deviations in shapes that result from, for example, the manufacturing process. The term “and/or” used herein includes each and every combination of one or more of the stated components. In addition, as used herein, the term “substrate” may refer to the substrate itself, or a laminated structure including the substrate and a certain layer or film formed on a surface thereof. In addition, the term “surface of the substrate” may mean an exposed surface of the substrate itself, or an outer side surface such as a certain layer or film formed on the substrate.

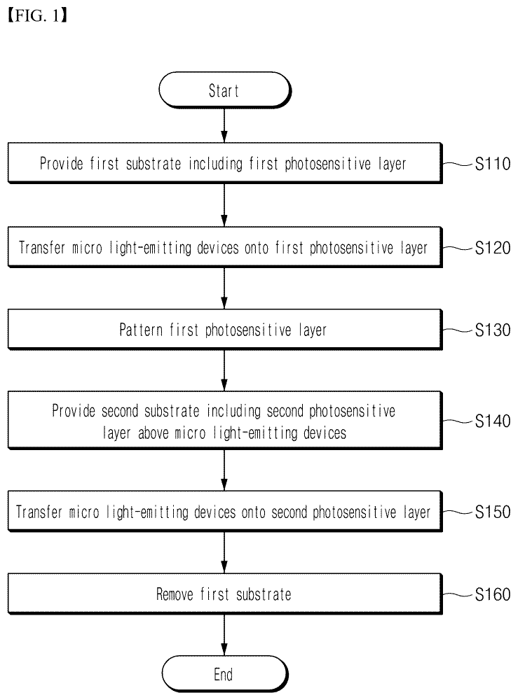

FIG. 1 is a flowchart illustrating a method of transferring micro light-emitting devices according to one embodiment of the present invention. FIGS. 2 to 10 are perspective views or side views schematically illustrating the method of transferring micro light-emitting devices according to one embodiment of the present invention.

Referring to FIGS. 1 to 3, there is provided a source substrate S to which a plurality of micro light-emitting devices 110 are attached.

Any one of a sapphire substrate, a glass substrate, a quartz substrate, a silicon (Si) substrate, a gallium arsenide (GaAs) substrate, a gallium phosphide (GaP) substrate, a gallium arsenide phosphide (GaAsP) substrate, a silicon carbide (SiC) substrate, a gallium nitride (GaN) substrate, an aluminum nitride (AlN) substrate, a zinc oxide (ZnO) substrate, and a magnesium oxide (MgO) substrate may be used as the source substrate S.

In some embodiments, the source substrate S may be a semiconductor substrate. The source substrate S may be a semiconductor wafer. The plurality of micro light-emitting devices 110 may be, for example, micro light-emitting diode (LED) devices. Hereinafter, the plurality of micro light-emitting devices 110 will be described using micro LED devices.

In some embodiments, the source substrate may be a polymer substrate or a glass substrate. However, the present invention is not limited thereto.

The micro LED device may refer to an LED device with a size of 200 μm×200 μm or less. In order to implement a full-color display using the plurality of micro light-emitting devices 110, which are micro LED devices, as illustrated in FIG. 2, micro light-emitting devices (in FIG. 2, the plurality of micro light-emitting devices 110) with a desired emission wavelength may be fabricated on the source substrate S. In some embodiments, the plurality of micro light-emitting devices 110 may be any one of red micro LED devices, green micro LED devices, and blue micro LED devices. A person of ordinary skill in the art would understand that the emission wavelength may vary depending on a semiconductor bandgap. In some embodiments, the plurality of micro light-emitting devices 110 may be fabricated on a different substrate and then provided onto the source substrate S.

The blue micro LED devices may be fabricated based on GaN. The green micro LED devices may be based on GaN, but may be fabricated by adjusting the bandgap by changing a composition ratio of the material (InGaN) of a quantum well structure, which is a light-emitting region, to be different from that of the blue micro LED devices. The red micro LED devices may be fabricated based on GaAs.

The plurality of micro light-emitting devices 110 may each be provided on the source substrate S. In addition, the plurality of micro light-emitting devices 110 may be attached to the source substrate S by a source bonding layer 105. The plurality of micro light-emitting devices 110 may be fixed to the source substrate S with a predetermined adhesive force by the source bonding layer 105.

In some embodiments, the source bonding layer 105 may include an adhesion promoter resin, such as a polyimide resin, a photoresist (PR), or a resin like SU-8. In some embodiments, the source bonding layer 105 may include a photodecomposable polymer resin. In particular, the source bonding layer 105 may include a photodecomposable polymer resin that can undergo photodecomposition in response to laser light irradiation. However, the source bonding layer 105 is not limited to these materials, and any material capable of reducing the local bonding force through any controllable means, such as light, heat, electromagnetic waves, or the like, is sufficient.

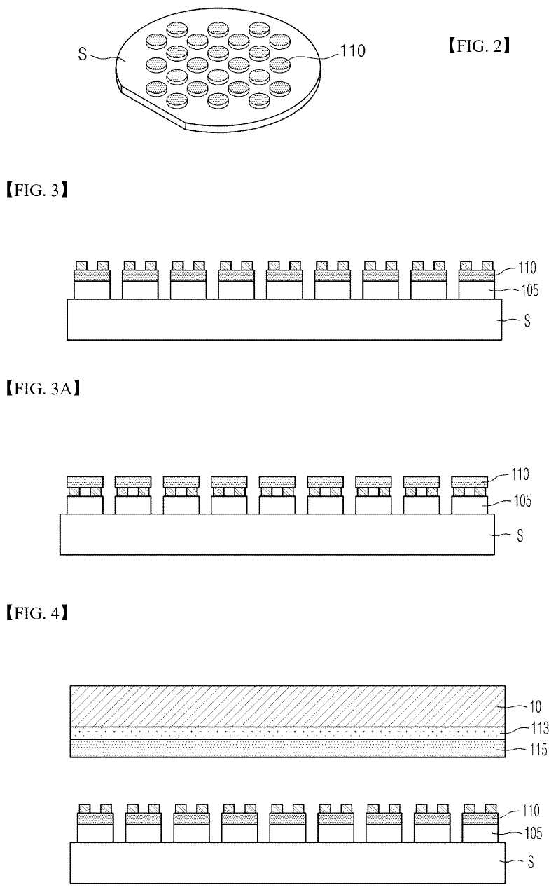

In FIG. 3, terminals of the micro light-emitting devices 110 are illustrated as being provided on top of the micro light-emitting devices 110, but the present invention is not limited thereto. As shown in FIG. 3A, in some embodiments, the terminals of the micro light-emitting devices 110 may be provided on the bottom of the micro light-emitting devices 110. When the terminals of the micro light-emitting devices 110 are provided on the bottom of the micro light-emitting devices 110, the terminals may be embedded in the source bonding layer 105.

Referring to FIG. 4, a first substrate 10 may be provided to face the plurality of micro light-emitting devices 110 provided on the source substrate S (S110). The first substrate 10 may face the source substrate S with the plurality of micro light-emitting devices 110 interposed therebetween.

The first substrate 10 may include a first photosensitive layer 113 and a first adhesive layer 115 on a surface thereof facing the source substrate S.

The first substrate 10 may be, for example, any one of a semiconductor substrate, a glass substrate, and a polymer substrate, but the present invention is not limited thereto. For example, as the semiconductor substrate, any one of a sapphire substrate, a glass substrate, a quartz substrate, silicon (Si) substrate, a gallium arsenide (GaAs) substrate, a gallium phosphide (GaP) substrate, a gallium arsenide phosphide (GaAsP) substrate, a silicon carbide (SiC) substrate, a gallium nitride (GaN) substrate, an aluminum nitride (AlN) substrate, a zinc oxide (ZnO) substrate, and a magnesium oxide (MgO) substrate may be used, but the present invention is not limited thereto.

The first substrate 10 may include the first photosensitive layer 113. The first photosensitive layer 113 may include any material that can undergo photodecomposition in response to laser light or ultraviolet (UV) light. In some embodiments, the first photosensitive layer 113 may include an adhesion promoter resin, such as a polyimide resin, a photoresist (PR), or a resin like SU-8. However, the present invention is not limited thereto.

In some embodiments, the first substrate 10 may further include the first adhesive layer 115. The first adhesive layer 115 may be formed on the first photosensitive layer 113 and serves to attach the plurality of micro light-emitting devices 110.

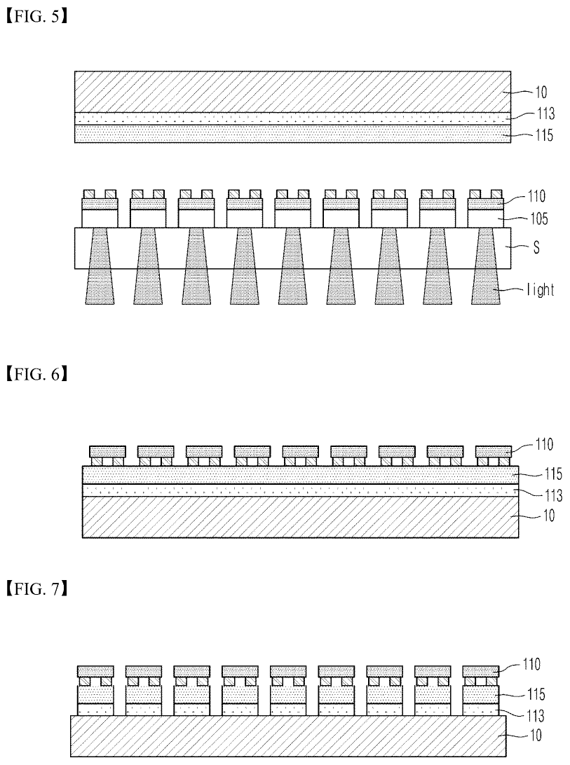

Referring to FIG. 5, light may be irradiated onto the source bonding layer 105 through the source substrate S so that the plurality of micro light-emitting devices 110 are transferred onto the first photosensitive layer 113 (S120).

The source bonding layer 105 irradiated with light may undergo photodecomposition, thereby reducing or eliminating an adhesive force between the plurality of micro light-emitting devices 110 and the source substrate S. The light may be UV light or laser light. The source substrate S may be substantially transparent to the light irradiated onto the source bonding layer 105. Here, being substantially transparent to the light irradiated onto the source bonding layer 105 means that a absorption rate of the light irradiated onto the source bonding layer 105 and absorbed by the source substrate S is less than 40%.

In some embodiments, by at least partially undergoing photodecomposition, the source bonding layer 105 generates a large amount of gas and vaporizes, and the pressure from the generated gas causes a rapid volume change in the source bonding layer 105, thereby providing the kinetic energy required to transfer the plurality of micro light-emitting devices 110 onto the first adhesive layer 115. Due to the light irradiation, the source bonding layer 105 may undergo photodecomposition only near the irradiated surface, or the entire source bonding layer 105 may undergo photodecomposition.

In FIG. 5, the plurality of micro light-emitting devices 110 are illustrated as being irradiated with light while being separated from the first adhesive layer 115, but the present invention is not limited thereto. In some embodiments, the plurality of micro light-emitting devices 110 may also be irradiated with light while in contact with the first adhesive layer 115.

In FIG. 5, it is illustrated that light is irradiated onto all the micro light-emitting devices 110, but a person of ordinary skill in the art will understand that light can be irradiated only onto the micro light-emitting devices 110 intended to be transferred to the first substrate 10.

Referring to FIG. 6, the plurality of micro light-emitting devices 110 may be transferred onto the first substrate 10 by the light irradiation.

By the transfer, of the two principal surfaces of each of the micro light-emitting devices 110, the principal surface that was in contact with the source bonding layer 105 becomes a free surface, and the principal surface opposite thereto may come into contact with the first adhesive layer 115. Thereafter, the source substrate S may be removed.

Referring to FIGS. 1 and 7, the first photosensitive layer 113 and the first adhesive layer 115 are patterned to correspond to shapes of the micro light-emitting devices 110 (S130). Here, patterning the first photosensitive layer 113 and the first adhesive layer 115 to correspond to the shapes of the micro light-emitting devices 110 means etching the first photosensitive layer 113 and the first adhesive layer 115 using the micro light-emitting devices 110 as a patterning mask. Thus, outlines of the patterned first photosensitive layer 113 and first adhesive layer 115 are not necessarily required to match outer edges of the micro light-emitting devices 110.

In some embodiments, the first photosensitive layer 113 and the first adhesive layer 115 may have shapes that are substantially the same as planar outlines of the micro light-emitting devices 110 by the patterning.

In some embodiments, the patterning may be performed by dry etching, but the present invention is not limited thereto.

Further, by the patterning, the first photosensitive layer 113 and the first adhesive layer 115 may each be divided to correspond to each of the micro light-emitting devices 110.

Referring to FIGS. 1 and 8, a second substrate 20 including a second photosensitive layer 123 and a second adhesive layer 125 is provided above the micro light-emitting devices 110 (S140). The second substrate 20 may be disposed to face the micro light-emitting devices 110 on the first substrate 10. The second substrate 20 may face the first substrate 10 with the plurality of micro light-emitting devices 110 interposed therebetween.

The second substrate 20 may be, for example, any one of a semiconductor substrate, a glass substrate, and a polymer substrate, but the present invention is not limited thereto. For example, as the semiconductor substrate, any one of a sapphire substrate, a glass substrate, a quartz substrate, silicon (Si) substrate, a gallium arsenide (GaAs) substrate, a gallium phosphide (GaP) substrate, a gallium arsenide phosphide (GaAsP) substrate, a silicon carbide (SiC) substrate, a gallium nitride (GaN) substrate, an aluminum nitride (AlN) substrate, a zinc oxide (ZnO) substrate, and a magnesium oxide (MgO) substrate may be used, but the present invention is not limited thereto.

The second substrate 20 may include the second photosensitive layer 123. The second photosensitive layer 123 may include any material that can undergo photodecomposition in response to laser light or ultraviolet (UV) light. In some embodiments, the second photosensitive layer 123 may include an adhesion promoter resin, such as a polyimide resin, a photoresist (PR), or a resin like SU-8. However, the present invention is not limited thereto.

In some embodiments, the second adhesive layer 125 may be further provided on the second substrate 20. The second adhesive layer 125 may be formed on the second photosensitive layer 123 and serves to attach the plurality of micro light-emitting devices 110.

In some embodiments, the second photosensitive layer 123 and the second adhesive layer 125 may be sequentially provided on the second substrate 20, and the micro light-emitting devices 110 may be oriented such that the second substrate 20 faces the second adhesive layer 125.

In some embodiments, the material of the second adhesive layer 125 may be substantially the same as the material of the first adhesive layer 115. In some embodiments, the material of the second photosensitive layer 123 may be substantially the same as the material of the first photosensitive layer 113.

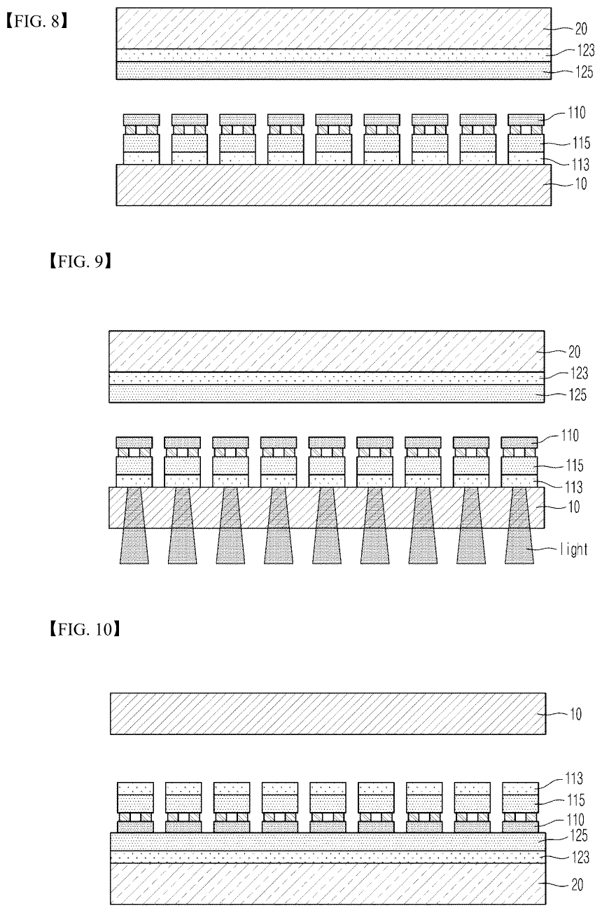

Referring to FIGS. 1 and 9, light may be irradiated onto the first photosensitive layer 113 through the first substrate 10 so that the plurality of micro light-emitting devices 110 are transferred onto the second photosensitive layer 123 (S150). The first photosensitive layer 113 irradiated with light may undergo photodecomposition, thereby reducing or eliminating an adhesive force between the micro light-emitting devices 110 and the first substrate 10. The light may be UV light or laser light. The first substrate 10 may be substantially transparent to the light irradiated onto the first photosensitive layer 113. Here, being substantially transparent to the light irradiated onto the first photosensitive layer 113 means that an absorption rate of the light irradiated onto the first photosensitive layer 113 and absorbed by the first substrate 10 is less than 40%.

In some embodiments, by at least partially undergoing photodecomposition, the first photosensitive layer 113 generates a large amount of gas and vaporizes, and the pressure from the generated gas causes a rapid volume change in the first photosensitive layer 113, thereby providing the kinetic energy required to transfer the plurality of micro light-emitting devices 110 onto the second adhesive layer 125. Due to the light irradiation, the first photosensitive layer 113 may undergo photodecomposition only near the irradiated surface, or the entire first photosensitive layer 113 may undergo photodecomposition.

In FIG. 9, the plurality of micro light-emitting devices 110 are illustrated as being irradiated with light while being separated from the second adhesive layer 125, but the present invention is not limited thereto. In some embodiments, the plurality of micro light-emitting devices 110 may also be irradiated with light while in contact with the second adhesive layer 125.

In FIG. 9, it is illustrated that light is irradiated onto all the micro light-emitting devices 110, but a person of ordinary skill in the art will understand that light can be irradiated only onto the micro light-emitting devices 110 intended to be transferred to the second substrate 20.

Referring to FIGS. 1 and 10, after the micro light-emitting devices 110 have been transferred onto the second substrate 20, the first substrate 10 positioned to face the micro light-emitting devices 110 may be removed (S160).

The above process may be repeated one or more times as needed. Since the second substrate 20 also includes a photosensitive layer (i.e., the second photosensitive layer 123) and an adhesive layer (i.e., the second adhesive layer 125), it is possible, as needed, to achieve separation between the micro light-emitting devices 110 and the second substrate 20 by irradiating light.

Hereinafter, a method of continuously transferring the plurality of micro light-emitting devices 110, which have been transferred onto the second substrate 20, to an additional different substrate from the second substrate 20 will be described.

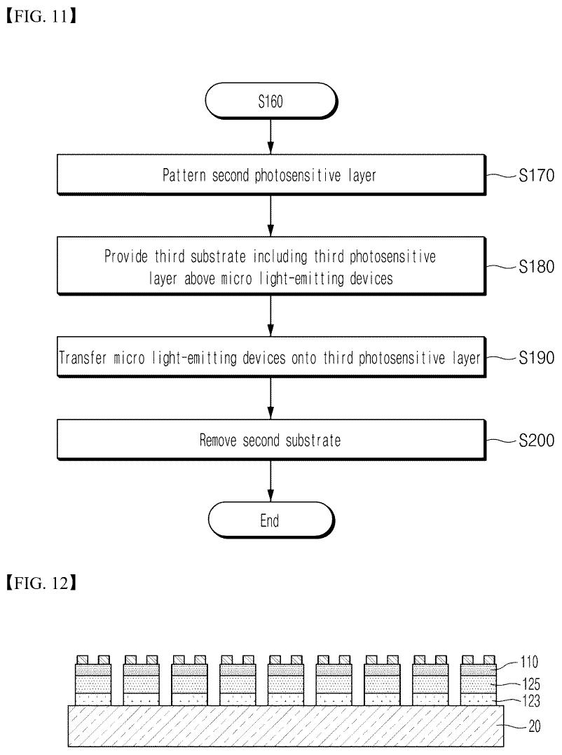

FIG. 11 is a flowchart illustrating a method of transferring micro light-emitting devices according to an additional embodiment of the present invention. FIGS. 12 to 16 are side views schematically illustrating the method of transferring micro light-emitting devices according to the additional embodiment of the present invention.

Referring to FIGS. 11 and 12, the second photosensitive layer 123 and the second adhesive layer 125 may be patterned to correspond to the shapes of the plurality of micro light-emitting devices 110 (S170). At this time, the first photosensitive layer 113 and the first adhesive layer 115 remaining on the other surface of the micro light-emitting devices 110 may be removed. Here, patterning the second photosensitive layer 123 and the second adhesive layer 125 to correspond to the shapes of the micro light-emitting devices 110 means etching the second photosensitive layer 123 and the second adhesive layer 125 using the micro light-emitting devices 110 as a patterning mask. Thus, outlines of the patterned second photosensitive layer 123 and second adhesive layer 125 are not necessarily required to match the outer edges of the micro light-emitting devices 110.

In some embodiments, the second photosensitive layer 123 and the second adhesive layer 125 may have shapes that are substantially the same as the planar outlines of the micro light-emitting devices 110 by the patterning. In some embodiments, the patterning may be performed by dry etching, but the present invention is not limited thereto.

Further, the second photosensitive layer 123 and the second adhesive layer 125 may each be divided to correspond to each of the micro light-emitting devices 110 by the patterning.

In some embodiments, the first photosensitive layer 113 remaining on the other surface of the micro light-emitting devices 110 may have already been removed by the light irradiation described with reference to FIG. 9.

Referring to FIG. 13, a third substrate 30 including a third photosensitive layer 133 and a third adhesive layer 135 is provided above the micro light-emitting devices 110 (S180). The third substrate 30 may be disposed to face the micro light-emitting devices 110 on the second substrate 20. The third substrate 30 may face the second substrate 20 with the plurality of micro light-emitting devices 110 interposed therebetween.

The third substrate 30 may be, for example, any one of a semiconductor substrate, a glass substrate, and a polymer substrate, but the present invention is not limited thereto. For example, as the semiconductor substrate, any one of a sapphire substrate, a glass substrate, a quartz substrate, silicon (Si) substrate, a gallium arsenide (GaAs) substrate, a gallium phosphide (GaP) substrate, a gallium arsenide phosphide (GaAsP) substrate, a silicon carbide (SiC) substrate, a gallium nitride (GaN) substrate, an aluminum nitride (AlN) substrate, a zinc oxide (ZnO) substrate, and a magnesium oxide (MgO) substrate may be used, but the present invention is not limited thereto.

The third substrate 30 may include the third photosensitive layer 133. The third photosensitive layer 133 may include any material that can undergo photodecomposition in response to laser light or ultraviolet (UV) light. In some embodiments, the third photosensitive layer 133 may include an adhesion promoter resin, such as a polyimide resin, a photoresist (PR), or a resin like SU-8. However, the present invention is not limited thereto.

In some embodiments, the third adhesive layer 135 may be further provided on the third substrate 30. The third adhesive layer 135 may be formed on the third photosensitive layer 133 and serves to attach the plurality of micro light-emitting devices 110.

In some embodiments, the third photosensitive layer 133 and the third adhesive layer 135 may be sequentially provided on the third substrate 30, and the third substrate 30 may be oriented such that the micro light-emitting devices 110 face the third adhesive layer 135.

In some embodiments, the material of the third adhesive layer 135 may be substantially the same as the material of the second adhesive layer 125. In some embodiments, the material of the third photosensitive layer 133 may be substantially the same as the material of the second photosensitive layer 123.

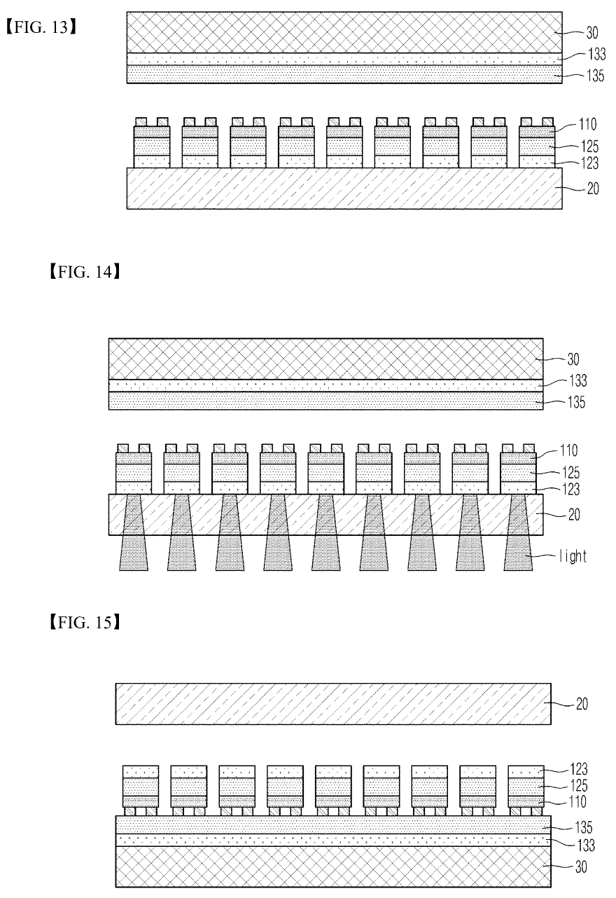

Referring to FIG. 14, light may be irradiated onto the second photosensitive layer 123 through the second substrate 20 so that the plurality of micro light-emitting devices 110 are transferred onto the third photosensitive layer 133 (S190). The second photosensitive layer 123 irradiated with light may undergo photodecomposition, thereby reducing or eliminating an adhesive force between the micro light-emitting devices 110 and the second substrate 20. The light may be UV light or laser light. The second substrate 20 may be substantially transparent to the light that is irradiated onto the second photosensitive layer 123. Here, being substantially transparent to the light irradiated onto the second photosensitive layer 123 means that an absorption rate of the light irradiated onto the second photosensitive layer 123 and absorbed by the second substrate 20 is less than 40%.

In some embodiments, by at least partially undergoing photodecomposition, the second photosensitive layer 123 generates a large amount of gas and vaporizes, and the pressure from the generated gas causes a rapid volume change in the second photosensitive layer 123, thereby providing the kinetic energy required to transfer the plurality of micro light-emitting devices 110 onto the third adhesive layer 135. Due to the light irradiation, the second photosensitive layer 123 may undergo photodecomposition only near the irradiated surface, or the entire second photosensitive layer 123 may undergo photodecomposition.

In FIG. 14, the plurality of micro light-emitting devices 110 are illustrated as being irradiated with light while being separated from the third adhesive layer 135, but the present invention is not limited thereto. In some embodiments, the plurality of micro light-emitting devices 110 may also be irradiated with light while in contact with the third adhesive layer 135.

In FIG. 14, it is illustrated that light is irradiated onto all the micro light-emitting devices 110, but a person of ordinary skill in the art will understand that light can be irradiated only onto the micro light-emitting devices 110 intended to be transferred to the third substrate 30.

Referring to FIG. 15, after the micro light-emitting devices 110 have been transferred onto the third substrate 30, the second substrate 20 positioned to face the micro light-emitting devices 110 may be removed (S200).

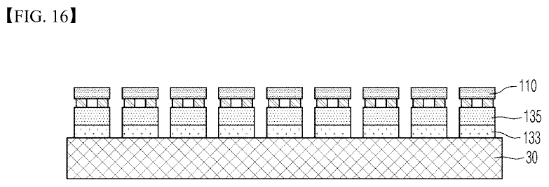

Referring to FIG. 16, the third photosensitive layer 133 and the third adhesive layer 135 may be patterned to correspond to the shapes of the micro light-emitting devices 110. At this time, the second photosensitive layer 123 and the second adhesive layer 125 remaining on the other surface of the micro light-emitting devices 110 may be removed. Here, patterning the third photosensitive layer 133 and the third adhesive layer 135 to correspond to the shapes of the micro light-emitting devices 110 means etching the third photosensitive layer 133 and the third adhesive layer 135 using the micro light-emitting devices 110 as a patterning mask. Thus, outlines of the patterned third photosensitive layer 133 and third adhesive layer 135 are not necessarily required to match the outer edges of the micro light-emitting devices 110.

In some embodiments, the third photosensitive layer 133 and the third adhesive layer 135 may have shapes that are substantially the same as the planar outlines of the micro light-emitting devices 110 by the patterning. In some embodiments, the patterning may be performed by dry etching, but the present invention is not limited thereto.

Further, by the patterning, the third photosensitive layer 133 and the third adhesive layer 135 may each be divided to correspond to each of the micro light-emitting devices 110.

In some embodiments, the second photosensitive layer 123 remaining on the other surface of the micro light-emitting devices 110 may have already been removed by the light irradiation described with reference to FIG. 14.

By repeating the above process one or more times as described above, the orientations of the micro light-emitting devices 110 may be adjusted as needed. For example, a direction of the electrodes provided on the micro light-emitting devices 110 may be adjusted to face upward or downward as needed.

In addition, the micro light-emitting devices 110 can be transferred to different substrates as many times as needed, and only the required number of micro light-emitting devices 110 can be transferred to a predetermined desired position.

While the embodiments of the present invention have been described in detail above, those skilled in the art to which the present invention pertains will appreciate that various modifications and variations can be made to the present invention without departing from the spirit and scope of the invention as defined by the appended claims. Accordingly, future modifications of the embodiments of the present invention will not depart from the scope of the present invention.

1. A method of transferring micro light-emitting devices, comprising:
providing a first substrate including a first photosensitive layer and a first adhesive layer;
providing micro light-emitting devices on the first adhesive layer;
patterning the first photosensitive layer and the first adhesive layer to correspond to shapes of the micro light-emitting devices;
providing a second substrate, which includes a second photosensitive layer and a second adhesive layer, above the micro light-emitting devices; and
irradiating light onto the first photosensitive layer through the first substrate to transfer the micro light-emitting devices onto the second substrate.

2. The method of claim 1, wherein the patterning of the first photosensitive layer and the first adhesive layer is performed by anisotropic etching.

3. The method of claim 1, wherein the first photosensitive layer includes a material that is photodecomposable by light irradiation.

4. The method of claim 3, wherein the first photosensitive layer includes a material that is photodecomposable in response to laser light or ultraviolet (UV) light

5. The method of claim 1, wherein the second photosensitive layer and the second adhesive layer are sequentially provided on the second substrate, and
the providing of the second substrate, which includes the second photosensitive layer and the second adhesive layer, above the micro light-emitting devices is performed such that the second adhesive layer faces the micro light-emitting devices.

6. The method of claim 1, further comprising:
after the irradiating of light onto the first photosensitive layer through the first substrate,
patterning the second photosensitive layer and the second adhesive layer to correspond to the shapes of the micro light-emitting devices;
providing a third substrate, which includes a third photosensitive layer and a third adhesive layer, above the micro light-emitting devices;
irradiating light onto the second photosensitive layer through the second substrate; and
separating the second substrate from the micro light-emitting devices to transfer the micro light-emitting devices onto the third substrate.

7. The method of claim 6, wherein the patterning of the second photosensitive layer and the second adhesive layer to correspond to the shapes of the micro light-emitting devices is performed by anisotropic etching using the micro light-emitting devices as an etching mask.

8. The method of claim 6, wherein residual portions of the first photosensitive layer and the first adhesive layer are removed during the patterning of the second photosensitive layer and the second adhesive layer to correspond to the shapes of the micro light-emitting devices.

9. The method of claim 6, wherein a material of the second photosensitive layer is substantially the same as a material of the first photosensitive layer.

10. The method of claim 6, wherein, in the irradiating of light onto the first photosensitive layer through the first substrate, the micro light-emitting devices are irradiated with light while being spaced apart from the second substrate.

11. A method of transferring micro light-emitting devices, comprising:
providing a first substrate including a first photosensitive layer;
placing micro light-emitting devices on the first photosensitive layer;
patterning the first photosensitive layer so that shapes of the micro light-emitting devices are transferred;
attaching a second substrate including a second photosensitive layer on top of the micro light-emitting devices; and
irradiating light onto the first photosensitive layer through the first substrate to transfer the micro light-emitting devices onto the second substrate.

12. The method of claim 11, wherein the first substrate and the second substrate are substantially transparent to the light irradiated onto the first photosensitive layer.

13. The method of claim 11, further comprising:
after the irradiating of light onto the first photosensitive layer through the first substrate,
patterning the second photosensitive layer to correspond to the shapes of the micro light-emitting devices;
providing a third substrate, which includes a third photosensitive layer, above the micro light-emitting devices; and
irradiating light onto the second photosensitive layer through the second substrate to transfer the micro light-emitting devices onto the third substrate.

14. The method of claim 11, wherein a material of the third photosensitive layer is substantially the same as a material of the first photosensitive layer.

15. The method of claim 11, wherein a residual portion of the first photosensitive layer is removed during the patterning of the second photosensitive layer to correspond to the shapes of the micro light-emitting devices.
